(19) United States
(12) Patent Application Publication
(10) Pub. No.: US 2016/0218260 A1
(43) Pub. Date: Jul. 28, 2016

(54) A LIGHT EMITTING DEVICE

(71) Applicant: PHILIPS LIGHTING HOLDING B.V., Eindhoven (NL)

(72) Inventors: Rifat Ata Mustafa Hikmet, Eindhoven (NL); Ties Van Bommel, Horst (NL)

(21) Appl. No.: 14/917,517

(22) PCT Filed: Aug. 25, 2014
(86) PCT No.: PCT/EP2014/067953

§ 371 Date: Mar. 8, 2016

(30) Foreign Application Priority Data
Sep. 10, 2013 (EP) 13183729.6
Sep. 10, 2013 (EP) 13183783.3

(51) Int. Cl. H01L 33/60; F21V 8/00; H01L 33/00; H01L 27/15; H01L 33/58

(52) U.S. Cl. CPC H01L 33/60; H01L 27/153; H01L 33/58; H01L 33/005; G02B 6/0028; G02B 6/0073; G02B 6/0068

(57) ABSTRACT

A light emitting device (1) comprising plurality of solid state light sources (21, 22, 23), and a transparent substrate (3) comprising a first light input surface (31) and a first light exit surface (32) extending in an angle different from zero to one another, the transparent substrate (3) being adapted for receiving light (13) emitted by the plurality of light sources (21, 22, 23) at the first light input surface (31), guiding the light (13) to the first light exit surface (32) and coupling the light (13) out of the first light exit surface (32), wherein active layers of the plurality of solid state light sources (21, 22, 23) are provided in direct physical contact with the first light input surface (31) of the transparent substrate (32) and wherein the first light input surface has a larger surface area than the first light exit surface.

### FIELD OF THE INVENTION

The invention concerns a light emitting device comprising plurality of solid state light sources, such as a Light Emitting Diode (LED), and a transparent substrate.

### BACKGROUND OF THE INVENTION

U.S. Pat. No. 7,737,460 B2 describes a white LED chip including an LED chip formed on a main surface of a sapphire substrate. A light extracting film is provided on the other main surface of the sapphire substrate. The two main surfaces extend opposite and parallel to one another. Furthermore, a phosphor member for generating white light may be provided on an opposite side of the substrate with respect to the light extracting film.

High brightness light sources are interesting for various applications including spot lighting, stage-lighting, automotive lighting and digital (front) projection. For this purpose, it is possible to make use of so-called light concentrators where shorter wavelength light is converted to longer wavelengths in a highly transparent luminescent material.

However, in the above mentioned light emitting device various effects such as re-absorption, scattering, and thermal quenching due to excess heating of the phosphor can reduce the system efficiency considerably.

EP2346101A1 discloses a light-emitting module wherein an optical wavelength conversion ceramic converts the wavelength of light emitted by a semiconductor light emitting element which is mounted on a element-mounting substrate. The optical wavelength conversion ceramic is provided with a full-spectrum transmittance in the optical wavelength conversion range of at least 40% transparency. A reflective film is provided on the surface of the optical wavelength conversion ceramic. The emission area of the light which passed through the optical wavelength conversion ceramic is narrowed to be smaller than the light emission area of the semiconductor light-emitting element. The reflective film guides the light so that the light is emitted roughly parallel to the light-emitting surface of the semiconductor light-emitting element.

### SUMMARY OF THE INVENTION

It is an object of the present invention to overcome this problem, and to provide a light emitting device with which re-absorption, scattering, and thermal quenching is reduced or even eliminated, and with which the system efficiency is thus improved.

According to a first aspect of the invention, this and other objects are achieved by means of a light emitting device comprising a plurality of solid state light sources, and a transparent substrate comprising a first light input surface and a first light exit surface extending in an angle different from zero to one another, the transparent substrate being adapted for receiving light emitted by the plurality of solid state light sources at the first light input surface, guiding the light to the first light exit surface and coupling the out of the first light exit surface, wherein active layers of the plurality of solid state light sources are provided in direct physical contact with the first light input surface of the transparent substrate and wherein the first light input surface has a larger surface area than the first light exit surface.

By providing a transparent substrate adapted for guiding light a light emitting device is provided with which a high fraction of the light emitted by the plurality of solid state light sources and coupled into the transparent substrate is guided towards the first light exit surface. Furthermore absorption/scattering losses within the substrate are reduced considerably.

By providing the first light input surface and the first light exit surface of the transparent substrate such that they extend in an angle different from zero to one another, and particularly extending perpendicular to each other, a light emitting device is provided in which more light is coupled into the transparent substrate and with which an optimally large amount of light is guided towards the first light exit surface by means of TIR (Total Internal Reflection). This in turn further lowers the amount of light lost by exiting the transparent substrate through other surfaces than the light exit surface and thus further increases the intensity of the light emitted through the first light exit surface.

By providing the active layers of the plurality of solid state light sources in direct physical contact with the transparent substrate, a light emitting device is provided with which a particularly large amount of the light emitted from the solid state light source is coupled into and confined within the transparent substrate. The direct physical contact between the active layers of the plurality of solid state light sources and the transparent substrate may result in a matching lattice structure at the first light input surface of the active layers of the plurality of solid state light sources and the transparent substrate. In other words, the crystal structure of the active layers of the plurality of solid state light sources matches, or is substantially similar to, the crystal structure of the transparent substrate at the first light input surface, meaning that there is a smooth transition of the crystal structure from the transparent substrate to the active layers of the plurality of solid state light sources reducing, for example, scattering losses at the first light input surface. This may be the result of growing, for example using epitaxial growth, the active layers of the plurality of solid state light sources directly on the first light input surface of the transparent substrate, resulting in the matching lattice structure. The transparent substrate is for example a growth substrate and/or a single crystal substrate. These substrates provide for improved coupling of light into the transparent substrate emitted by the plurality of solid state light sources, because of the smooth transition between the active layers of the plurality of light sources and the transparent substrate at the first light input surface.

Furthermore, by providing the first light input surface with a larger surface area than the first light exit surface a light emitting device is provided in which the substrate has a light concentrating effect such that the intensity of the light coupled out of the substrate is further increased.

The above features all contribute to that re-absorption, scattering, and thermal quenching occurring in the light emitting device is reduced considerably, which in turn leads to a high intensity light output and thus a considerably improved system efficiency. In embodiments the area of the first light input surface is four times larger, ten times larger or thirty times larger than the surface area of the first light exit surface.

In an embodiment the plurality of solid state light sources is arranged on a heat sink, such that the plurality of solid state light sources is arranged in between the transparent substrate and the heat sink. By providing a heat sink the heat produced by the light sources may in an efficient manner be dissipated away from the transparent substrate which functions as a light guide.

In an embodiment the transparent substrate comprises one or more of a photonic crystal structure and a diffractive structure. By providing the substrate with a photonic crystal structure and/or a diffractive structure a peak intensity of the light coupled out of the transparent substrate having a direction different from a normal to the light input surface of the substrate, and thus to the surface of the solid state light source, is obtained. In embodiments, the photonic crystal structure and/or diffractive structure is of a type providing the light coupled out of the transparent substrate with a radiation pattern not being lambertian but rather having more emission in sideways directions and in embodiments concentrated within an angular range of 33 to 47 degrees with respect to the normal to the light input surface of the substrate, and thus to the surface of the solid state light source. Particularly, the use of photonic crystal structures in the substrate provides for light emitted by the solid state light source being confined outside the escape cone angles of the surfaces of the substrate different from the light exit surface. Furthermore the photonic crystal structures may be designed so that the angular distribution of the emission is such that the amount of light falling onto the areas covered by the solid state light source is minimized. All in all the use of photonic crystal structures and/or diffractive structures thus contributes to a further increase of the intensity of the light coupled out of the substrate.

In an embodiment the transparent substrate comprises a coupling element arranged at the first light exit surface for coupling light out of the first light exit surface. Thereby a light emitting device is provided with which the coupling of light out of the transparent substrate is considerably more efficient, which leads to less loss of light and thus a higher intensity gain.

In embodiments each of the plurality of light sources emits light of a first spectral distribution. In other embodiments the plurality of light sources comprise at least one first solid state light source emitting light of a first spectral distribution and at least one second solid state light source emitting light of a second spectral distribution, different from the first spectral distribution. Then different spectral distributions are received by the transparent substrate, guided to the first light exit surface and emitted from the first light exit surface. In this way a pre-determined colored light is emitted at the first light exit surface of the transparent substrate obtained by applying different solid state light sources that emit different spectral distributions.

In an embodiment the transparent substrate is made of a transparent material which is chosen from the group comprising sapphire, undoped transparent garnets, such as YAG, LuAG, glass, quartz, ceramic materials such as polycrystalline alumina, luminescent materials, phosphors and combinations thereof. Thereby a light emitting device is provided having a substrate made of a highly transparent material with a high heat conductivity, thus allowing light from the plurality of solid state light sources to be guided through the transparent substrate with very small or even no loss of light while simultaneously ensuring excellent heat dissipation. in embodiments, the transparent material shows a high transparency, in other words it should not scatter light.

In this context a material being highly transparent is intended to be a material showing almost no absorbance in the spectral ranges of excitation and emission, and further showing direct beam transparency of more than 80%, more than 90%, more than 95% or even more than 98% (i.e. the fraction of a parallel beam of light scattered to angles higher than 2 degrees is less than 20%, less than 10%, less than 5% or even less than 2%).

In an embodiment the transparent substrate comprises any one or more of a luminescent element and an optical element arranged at the first light exit surface. By providing a luminescent element at the first light exit surface a light emitting device is provided which ensures conversion of light having one spectral distribution to light having another spectral distribution, the advantages of which are described further below. By providing an optical element at the first light exit surface the patterns and shapes of the light beam emitted by the light emitting device may be adjusted to a specific application or situation. For instance the image pattern obtained may be filtered, such as filtered by color or polarization, focused, shaped or projected onto a surface. Suitable optical elements include, but are not limited to, refractive or diffractive elements, e.g. lenses, color filters, reflective elements, polarizers and pinholes as well as combinations of such elements.

In an embodiment the transparent substrate is adapted for converting at least a part of the light emitted by the plurality of solid state light sources to light with a different spectral distribution.

Thereby a light emitting device is provided which ensures conversion of light which otherwise cannot be maintained in the light guiding substrate to different, particularly longer, wavelengths. Thereby such light may be reused to obtain multiple wavelengths with high efficiency and high brightness. Also, a light emitting device is provided with which the color pattern of the light emitted by the light emitting device may be changed. Furthermore, a light emitting device is provided with which a particularly large amount of the converted light will stay in the transparent substrate which can subsequently be extracted from one of the surfaces, which in turn leads to a particularly high intensity gain.

In an embodiment the light emitting device further comprises a light guide comprising a second light input surface and a second light exit surface, the light guide being adapted for receiving the light coupled out of the first light exit surface of the transparent substrate at the second light input surface, guiding the received light to the second light exit surface and coupling the received light out of the second light exit surface, the light guide being arranged such as to surround the transparent substrate at least partially.

In an embodiment the transparent substrate is embedded at least partially in the light guide. In this embodiment, the transparent substrate is in embodiments provided with a refractive index close to that of the light guide. The provision of such a light guide is particularly advantageous in embodiments in which more than one solid state light source is provided. By providing a light guide, a light emitting device is obtained with which light emitted by the plurality of solid state light sources and guided through the transparent substrate may be collected in a light guide and commonly guided to the second light exit surface in a particularly efficient way. This in turn leads to a further intensity gain and also to the possibility of providing a light output with a larger range of wavelengths, such as e.g. a white light output. By providing the light guide such as to surround the transparent substrate at least partially light may be collected not only from the first light exit surface but also from one or more of the other surfaces of the transparent substrate, although with the exception of the first light input surface at which the solid state light source is located, which in turn reduces light losses even further. Thereby a particularly efficient light collection from the transparent substrate and coupling of light into the light guide is ensured.

In an embodiment the light guide is further adapted for converting at least a part of the light received from the transparent substrate to light with a different spectral distribution. Thereby a light emitting device is provided which ensures conversion of light which otherwise cannot be maintained in the light guide to different, particularly longer, wavelengths. Thereby such light may be reused to obtain multiple wavelengths with high efficiency and high brightness. Also, a light emitting device is provided with which the color pattern of the light emitted by the light emitting device may be changed. Furthermore, a light emitting device is provided with which a particularly large amount of the converted light will stay in the light guide which can subsequently be extracted from one of the surfaces, which in turn leads to a particularly high intensity gain.

In an embodiment the light guide comprises any one of a transparent material, a luminescent material, a garnet, a doped garnet and any combination thereof. Thereby a light emitting device having a light guide with particularly good wavelength conversion properties is provided.

The invention further concerns a lamp, a luminaire or a lighting system comprising a light emitting device according to the invention and being used in one or more of the following applications: digital projection, automotive lighting, stage lighting, shop lighting, home lighting, accent lighting, spot lighting, theater lighting, fiber optic lighting, display systems, warning lighting systems, medical lighting applications, decorative lighting applications.

The invention further concerns a method for manufacturing a light emitting device, the method comprising the steps of:

providing a transparent substrate comprising a first light input surface and a first light exit surface extending in an angle different from zero to one another, the transparent substrate being adapted for guiding light which is received at the first light input surface, guiding the light to the first light exit surface and coupling the light out of the first light exit surface, wherein the first light input surface has a larger surface area than the first light exit surface, and

growing active layers of a plurality of solid state light sources on the first light input surface of the transparent substrate.

It is noted that the invention relates to all possible combinations of features recited in the claims.

### BRIEF DESCRIPTION OF THE DRAWINGS

This and other aspects of the present invention will now be described in more detail, with reference to the appended drawings showing embodiment(s) of the invention.

FIG. 1 shows a cross sectional view of a light emitting device comprising a phosphor wheel.

FIG. 2 shows side view of a light guide which is provided with an optical element at an exit surface.

FIG. 3 shows a perspective view of a light guide which is shaped throughout its length such as to provide a shaped light exit surface.

FIG. 4 shows a side view of a light guide which is shaped over a part of its length such as to provide a shaped light exit surface.

FIG. 5 shows a side view of a lighting system with a light guide and additional light sources and which is provided with a filter and a dichroic optical element.

FIG. 6 shows a perspective view of a light emitting device having a tapered exit surface.

FIG. 7A shows a perspective view of a first embodiment of a light emitting device according to the invention.

FIG. 7B shows a cross sectional view of the light emitting device according to FIG. 7A.

FIG. 8 shows a side view of a second embodiment of a light emitting device according to the invention.

FIG. 9 shows a perspective view of a third embodiment of a light emitting device according to the invention and comprising a light guide.

FIG. 10 shows a side view of a fourth embodiment of a light emitting device according to the invention and comprising a light guide.

FIG. 11 shows a side view of a fifth embodiment of a light emitting device according to the invention.

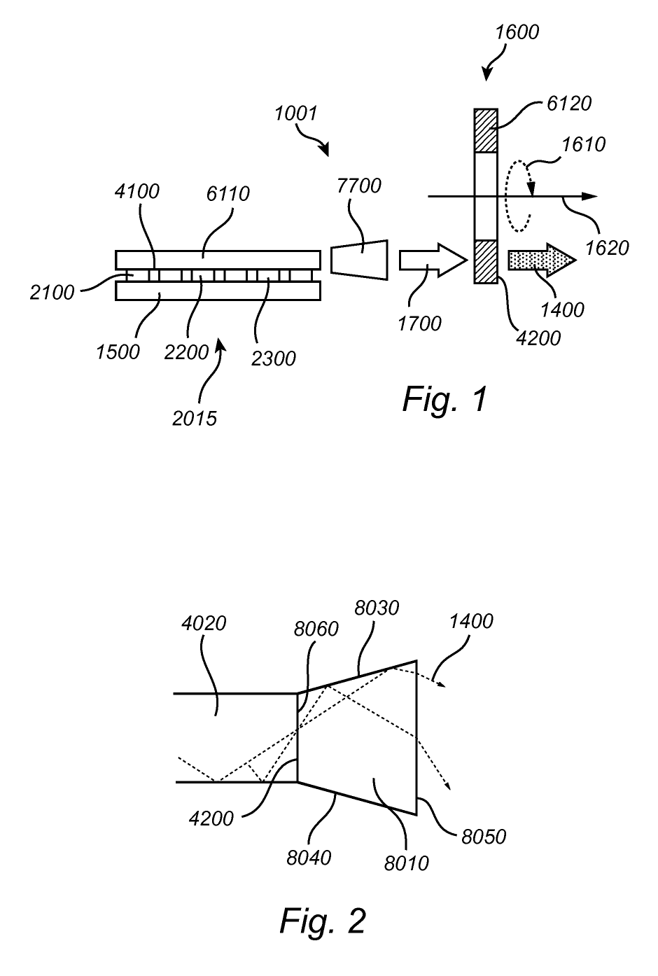

As illustrated in the figures, the sizes of layers, elements and regions are exaggerated for illustrative purposes and, thus, are provided to illustrate the general structures of embodiments of the present invention. Like reference numerals refer to like elements throughout, such that e.g. a light emitting device according to the invention is generally denoted 1, whereas different specific embodiments thereof are denoted by adding 01, 02, 03 and so forth to the general reference numeral. With regard to FIGS. 1 to 6 showing a number of features and elements which may be added to any one of the embodiments of a light emitting device according to the invention, “00” has been added to all elements except those specific to one of these Figures.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

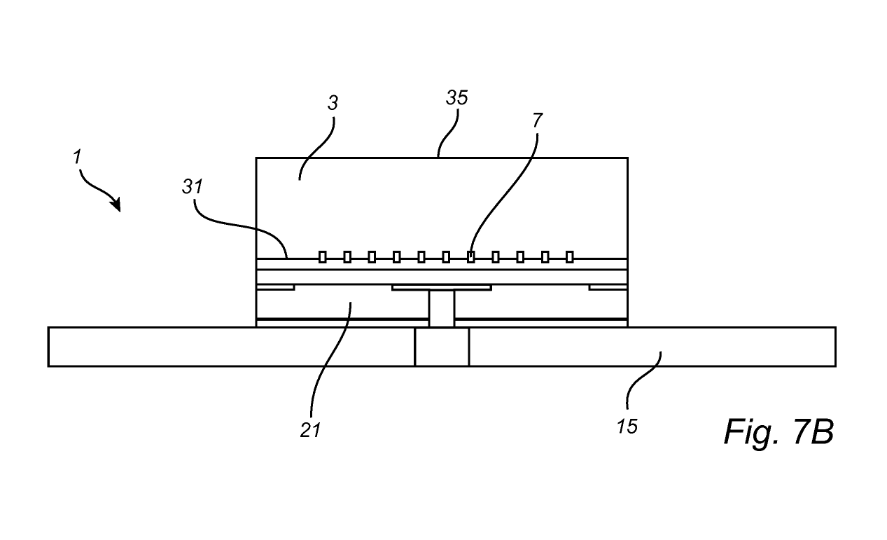

The following description will start with general considerations regarding applications, suitable light sources and suitable materials for various elements and features of a light emitting device according to the invention. For this purpose a number of features and elements which may be added to any one of the embodiments of a light emitting device according to the invention as set forth further below will be described with reference to FIGS. 1 to 6. The specific embodiments of a light emitting device according to the invention will be described in detail with reference to FIGS. 7A, 7B to 11.

A light emitting device according to the invention may be used in applications including but not being limited to a lamp, a light module, a luminaire, a spot light, a flash light, a projector, a digital projection device, automotive lighting such as e.g. a headlight or a taillight of a motor vehicle, arena lighting, theater lighting and architectural lighting.

Light sources which are part of the embodiments according to the invention as set forth below, are adapted for, in operation, emitting light with a first spectral distribution. This light is subsequently coupled into a light guide or waveguide. The light guide or waveguide may convert the light of the first spectral distribution to another spectral distribution and guides the light to an exit surface. The light source may in principle be any type of point light source, but is in an embodiment a solid state light source such as a Light Emitting Diode (LED), a Laser Diode or Organic Light Emitting Diode (OLED), a plurality of LEDs or Laser Diodes or OLEDs or an array of LEDs or Laser Diodes or OLEDs, or a combination of any of these. The LED may in principle be an LED of any color, or a combination of these, but is in an embodiment a blue light source producing light source light in the blue color-range which is defined as a wavelength range of between 380 nm and 495 nm. In another embodiment, the light source is an UV or violet light source, i.e. emitting in a wavelength range of below 420 nm. In case of a plurality or an array of LEDs or Laser Diodes or OLEDs, the LEDs or Laser Diodes or OLEDs may in principle be LEDs or Laser Diodes or OLEDs of two or more different colors, such as, but not limited to, UV, blue, green, yellow or red.

The light source may be a red light source, i.e. emitting in a wavelength range of e.g. between 600 nm and 800 nm. Such a red light source may be e.g. a light source of any of the above mentioned types directly emitting red light or provided with a phosphor suitable for converting the light source light to red light. This is particularly advantageous in combination with a light guide adapted for converting the light source light to infrared (IR) light, i.e. light with a wavelength of more than about 800 nm and in a suitable embodiment with a peak intensity in the range from 810 to 850 nm. Such a light guide for example comprises an IR emitting phosphor. A light emitting device with these characteristics is especially advantageous for use in night vision systems, but may also be used in any of the applications mentioned above.

Another example is combination of a first, red light source emitting light in a wavelength range between 480 nm and 800 nm and coupling this light into a transparent or luminescent rod or waveguide, for example a substrate, and a second light source, emitting blue or UV or violet light, i.e. with a wavelength smaller than 480 nm, and also coupling its emitted light into the transparent or luminescent waveguide or rod. In a luminescent rod or waveguide, the light of the second light source is converted by the luminescent waveguide or rod to a wavelength range between 480 nm and 800 nm, and the light of the first light source coupled into the luminescent waveguide or rod will not be converted. In other words, the second light source emits UV, violet or blue light and is subsequently converted by the luminescent concentrator into light in the green-yellow-orange-red spectral region. In another example the first light source emits in a wavelength range between 500 nm and 600 nm, and the light of the second light source is converted by the luminescent waveguide or rod to a wavelength range between 500 nm and 600 nm. In another example the first light source emits in a wavelength range between 600 nm and 750 nm, and the light of the second light source is converted by the luminescent waveguide or rod to a wavelength range between 600 nm and 750 nm.

Suitable materials for the light guides as set forth below according to embodiments of the invention are sapphire, single crystal GaN, polycrystalline alumina and/or undoped transparent garnets such as YAG, LuAG having a refractive index of n=1.7. An additional advantage of this material (above e.g. glass) is that it has a good thermal conductivity, thus diminishing local heating. Other suitable materials include, but are not limited to, glass, quartz and transparent polymers. In other embodiments the light guide material is lead glass. Lead glass is a variety of glass in which lead replaces the calcium content of a typical potash glass and in this way the refractive index can be increased. Ordinary glass has a refractive index of n=1.5, while the addition of lead produces a refractive index ranging up to 1.7.

The light guides, or substrates, as set forth below according to embodiments of the invention may comprise a suitable luminescent material for converting the light to another spectral distribution. Suitable luminescent materials include inorganic phosphors, such as doped YAG, LuAG, organic phosphors, organic fluorescent dyes and quantum dots which are highly suitable for the purposes of embodiments of the present invention as set forth below.

Quantum dots are small crystals of semiconducting material generally having a width or diameter of only a few nanometers. When excited by incident light, a quantum dot emits light of a color determined by the size and material of the crystal. Light of a particular color can therefore be produced by adapting the size of the dots. Most known quantum dots with emission in the visible range are based on cadmium selenide (CdSe) with a shell such as cadmium sulfide (CdS) and zinc sulfide (ZnS). Cadmium free quantum dots such as indium phosphide (InP), and copper indium sulfide (CuInS₂) and/or silver indium sulfide (AgInS₂) can also be used. Quantum dots show very narrow emission band and thus they show saturated colors. Furthermore the emission color can easily be tuned by adapting the size of the quantum dots. Any type of quantum dot known in the art may be used in embodiments of the present invention as set forth below. However, it may be preferred for reasons of environmental safety and concern to use cadmium-free quantum dots or at least quantum dots having very low cadmium content.

Organic fluorescent dyes can be used as well. The molecular structure can be designed such that the spectral peak position can be tuned. Examples of suitable organic fluorescent dyes materials are organic luminescent materials based on perylene derivatives, for example compounds sold under the name Lumogen® by BASF. Examples of suitable compounds include, but are not limited to, Lumogen® Red F305, Lumogen® Orange F240, Lumogen® Yellow F083, and Lumogen® F170.

The luminescent material may also be an inorganic phosphor. Examples of inorganic phosphor materials include, but are not limited to, cerium (Ce) doped YAG (Y₃Al₅O₁₂) or LuAG (Lu₃A₁₅O₁₂). Ce doped YAG emits yellowish light, whereas Ce doped LuAG emits yellow-greenish light. Examples of other inorganic phosphors materials which emit red light may include, but are not limited to ECAS and BSSN; ECAS being Ca₁₋ₓAlSiN₃:Eux wherein 0<x≦1, in embodiments 0<x≦0.2; and BSSN being Ba_{2-x-z}MₓSi_{5-y}AlyN_{8-y}O_{y}: Eu_{z} wherein M represents Sr or Ca, 0<x≦1, 0<y≦4, and 0.0005≦z≦0.05, and in embodiments 0≦x≦0.2.

In embodiments of the invention as set forth below, the luminescent material is made of material selected from the group comprising (M<I>_{(1-x-y)}M<II>ₓM<III>_{y})₃ (M<IV>_{(1-z)}M<V>_{z})₅O₁₂ where M<I> is selected from the group comprising Y, Lu or mixtures thereof, M<II> is selected from the group comprising Gd, La, Yb or mixtures thereof, M<III> is selected from the group comprising Tb, Pr, Ce, Er, Nd, Eu or mixtures thereof, M<IV> is Al, M<V> is selected from the group comprising Ga, Sc or mixtures thereof, and 0<x≦1, 0<y≦0.1, 0<z<1, (M<I>_{(1-x-y)}M<II>ₓM<III>_{y})₂O₃ where M<I> is selected from the group comprising Y, Lu or mixtures thereof, M<II> is selected from the group comprising Gd, La, Yb or mixtures thereof, M<III> is selected from the group comprising Tb, Pr, Ce, Er, Nd, Eu, Bi, Sb or mixtures thereof, and 0<x≦1, 0<y≦0.1, (M<I>_{(1-x-y)}M<II>ₓM<III>_{y})S_{(1-z)}Se where M<I> is selected from the group comprising Ca, Sr, Mg, Ba or mixtures thereof, M<II> is selected from the group comprising Ce, Eu, Mn, Tb, Sm, Pr, Sb, Sn or mixtures thereof, M<III> is selected from the group comprising K, Na, Li, Rb, Zn or mixtures thereof, and 0<x≦0.01, 0<y≦0.05, 0≦z<1, (M<I>_{(1-x-y)}M<II>ₓM<III>_{y})O where M<I> is selected from the group comprising Ca, Sr, Mg, Ba or mixtures thereof, M<II> is selected from the group comprising Ce, Eu, Mn, Tb, Sm, Pr or mixtures thereof, M<III> is selected from the group comprising K, Na, Li, Rb, Zn or mixtures thereof, and 0<x≦0.1, 0<y≦0.1, (M<I>_{(z-x)}M<II>ₓM<III>₂)O₇ where M<I> is selected from the group comprising La, Y, Gd, Lu, Ba, Sr or mixtures thereof, M<II> is selected from the group comprising Eu, Tb, Pr, Ce, Nd, Sm, Tm or mixtures thereof, M<III> is selected from the group comprising Hf, Zr, Ti, Ta, Nb or mixtures thereof, and 0<x≦1, (M<I>₍₁₋ₓ₎M<II>ₓM<III>_{(1-y)}M<IV>_{y})O₃ where M<I> is selected from the group comprising Ba, Sr, Ca, La, Y, Gd, Lu or mixtures thereof, M<II> is selected from the group comprising Eu, Tb, Pr, Ce, Nd, Sm, Tm or mixtures thereof, M<III> is selected from the group comprising Hf; Zr, Ti, Ta, Nb or mixtures thereof, and M<IV> is selected from the group comprising Al, Ga, Sc, Si or mixtures thereof, and 0<x≦0.1, 0<y≦0.1, or mixtures thereof.

Other suitable luminescent materials are Ce doped Yttrium aluminum garnet (YAG, Y₃Al₅O₁₂) and Lutetium-Aluminum-Garnet (LuAG). A luminescent light guide may comprise a central emission wavelength within a blue color-range or within a green color-range or within a red color-range. The blue color-range is defined between 380 nanometer and 495 nanometer, the green color-range is defined between 495 nanometer and 590 nanometer, and the red color-range is defined between 590 nanometer and 800 nanometer. A selection of phosphors which may be used in embodiments is given in table 1 below along with the maximum emission wavelength.

TABLE 1

| Phosphor | Maximum emission wavelength [nm] |
|---|---|
| CaGa₂S₄:Ce | 475 |
| SrGa₂S₄:Ce | 450 |
| BaAl₂S₄:Eu | 470 |
| CaF₂:Eu | 435 |
| Bi₄Si₃O₁₂:Ce | 470 |
| Ca₃Sc₂Si₃O₁₂:Ce | 490 |

The transparent substrates, functioning as light guides, as set forth below according to embodiments of the invention may comprise regions with a different density of suitable luminescent material for converting the light to another spectral distribution. For example, a transparent substrate comprises two parts adjacent to each other and only one of which comprises a luminescent material and the other part is transparent or has a relatively low concentration of luminescent material. In another example the transparent substrate comprises yet another, third part, adjacent to the second part, which comprises a different luminescent material or a different concentration of the same luminescent material. The different parts may be integrally formed thus forming one piece or one transparent substrate. In an embodiment a partially reflecting element may be arranged between the different parts of the transparent substrate, for example between the first part and the second part. The partially reflecting element is adapted for transmitting light with one specific wavelength or spectral distribution and for reflecting light with another, different, specific wavelength or spectral distribution. The partially reflecting element may thus be a dichroic element such as a dichroic mirror.

FIG. 1 shows a light emitting device 1001 comprising a light guide, or transparent substrate, 4015 which may be adapted for converting incoming light with a first spectral distribution to light with a second, different from the first, spectral distribution. In another example, the light guide 4015 does not convert light to a different spectral distribution and only guides the incoming light. The light guide 4015 shown in FIG. 1 comprises or is constructed as a wavelength converter structure having another conversion part 6120 provided in the form of a rotatable phosphor wheel 1600, and it further comprises a coupling element 7700 arranged between the first conversion part 6110 and the second conversion part 6120 or phosphor wheel 1600.

The light emitting device 1001 further comprises a light source in the form of a plurality of LEDs 2100, 2200, 2300 arranged on a base or substrate 1500. The plurality of LEDs 2100, 2200, 2300 are used to pump the first conversion part 6110, which is in the embodiment shown made of a transparent material, to produce light 1700 having a third spectral distribution, such as green or blue light. The phosphor wheel 1600, which is rotating in a rotation direction 1610 about an axis of rotation 1620, is used for converting the light 1700 having the third spectral distribution to light 1400 having a second spectral distribution, such as red and/or green light. It is noted that in principle any combination of colors of the light 1700 and the light 1400 is feasible.

As shown in FIG. 1, illustrating the phosphor wheel 1600 in a cross sectional side view, the phosphor wheel 1600 is used in the transparent mode, i.e. incident light 1700 enters the phosphor wheel 1600 at one side, is transmitted through the phosphor wheel 1600 and emitted from an opposite side thereof forming the light exit surface 4200. Alternatively, the phosphor wheel 1600 may be used in the reflective mode (not shown) such that light is emitted from the same surface as the surface through which it enters the phosphor wheel.

The phosphor wheel 1600 may comprise only one phosphor throughout. Alternatively, the phosphor wheel 1600 may also comprise segments without any phosphor such that also part of the light 1700 may be transmitted without being converted. In this way sequentially other colors can be generated. In another alternative, the phosphor wheel 1600 may also comprise multiple phosphor segments, e.g. segments of phosphors emitting yellow, green and red light, respectively, such as to create a multi-colored light output. In yet another alternative, the light emitting device 1001 may be adapted for generating white light by employing a pixelated phosphor-reflector pattern on the phosphor wheel 1600.

In an embodiment the coupling element 7700 is an optical element suitable for collimating the light 1700 incident on the phosphor wheel 1600, but it may also be a coupling medium or a coupling structure such as e.g. the coupling medium or the coupling structure 7700 described above. The light emitting device 1001 may furthermore comprise additional lenses and/or collimators. For example, additional optics may be positioned such as to collimate the light emitted by the light sources 2100, 2200, 2300 and/or the light 1400 emitted by the light emitting device 1001.

FIG. 2 shows a transparent substrate, or light guide 4020, which comprises an optical element 8010 arranged with a light input facet 8060 in optical connection with a light exit surface 4200 of the light guide 4020. The optical element 8010 is made of a material having a high refractive index, in an embodiment a refractive index which is equal to or higher than that of the light guide 4020, and comprises a quadrangular cross section and two tapered sides 8030 and 8040. The tapered sides 8030 and 8040 are inclined outwardly from the light exit surface 4200 of the light guide 4020 such that the light exit facet 8050 of the optical element 8010 has a larger surface area than both the light input facet 8060 and the light exit surface 4200 of the light guide 4020. The optical element 8010 may alternatively have more than two, particularly four, tapered sides. In an alternative, the optical element 8010 has a circular cross section and one circumferential tapered side. With such an arrangement light will be reflected at the inclined sides 8030 and 8040 and has a large chance to escape if it hits the light exit facet 8050, as the light exit facet 8050 is large compared to the light input facet 8060. The shape of the sides 8030 and 8040 may also be curved and chosen such that all light escapes through the light exit facet 8050.

The optical element may also be integrally formed from the light guide 4020, for example by shaping a part of the transparent substrate such that a predetermined optical element is formed at one of the ends of the transparent substrate or light gudie. The optical element may for example have the shape of a collimator, or may have a cross-sectional shape of a trapezoid and in an embodiment outside surfaces of the trapezoid shape are provided with reflective layers. Thereby the received light may be shaped such as to comprise a larger spot size while simultaneously minimizing the loss of light through other surfaces than the light exit surface, thus also improving the intensity of the emitted light. In another embodiment the optical element has the shape of a lens array, for example convex or concave lenses or combinations thereof. Thereby the received light may be shaped such as to form focused light, defocused light or a combination thereof. In case of an array of lenses it is furthermore feasible that the emitted light may comprise two or more separate beams each formed by one or more lenses of the array. In more general terms, the transparent substrate or light guide may thus have differently shaped parts with different sizes. Thereby a light guide is provided with which light may be shaped in that any one or more of the direction of emission of light from the light exit surface, the beam size and beam shape of the light emitted from the light exit surface may be tuned in a particularly simple manner, e.g. by altering the size and/or shape of the light exit surface. Thus, a part of the light guide functions as an optical element.

The optical element may also be a light concentrating element (not shown) arranged at a light exit surface of the transparent substrate or light guide. The light concentrating element comprises a quadrangular cross section and two outwardly curved sides such that the light exit surface of the light concentrating element has a larger surface area than the light exit surface of the light guide. The light concentrating element may alternatively have more than two, particularly four, tapered sides. The light concentrating element may be a compound parabolic light concentrating element (CPC) having parabolic curved sides. In an alternative, the light concentrating element has a circular cross section and one circumferential tapered side. If, in an alternative, the refractive index of the light concentrating element is chosen to be lower than that of the light guide (but higher than that of air), still an appreciable amount of light can be extracted. This allows for a light concentrating element which is easy and cheap to manufacture compared to one made of a material with a high refractive index. For example, if the light guide has a refractive index of n=1.8 and the light concentrating element has a refractive index of n=1.5 (glass), a gain of a factor of 2 in light output may be achieved. For a light concentrating element with a refractive index of n=1.8, the gain would be about 10% more. Actually, not all light will be extracted since there will be Fresnel reflections at the interface between the optical element or the light concentrating element and the external medium, generally being air. These Fresnel reflections may be reduced by using an appropriate anti-reflection coating, i.e. a quarter-lambda dielectric stack or moth-eye structure. In case the light output as function of position over the light exit facet is inhomogeneous, the coverage with anti-reflection coating might be varied, e.g. by varying the thickness of the coating.

One of the interesting features of a CPC is that the etendue (=n²×area×solid angle, where n is the refractive index) of the light is conserved. The shape and size of the light input facet of the CPC can be adapted to those of the light exit surface of the light guide and/or vice versa. A large advantage of a CPC is that the incoming light distribution is transformed into a light distribution that fits optimally to the acceptable etendue of a given application. The shape of the light exit facet of the CPC may be e.g. rectangular or circular, depending on the desires. For example, for a digital projector there will be requirements to the size (height and width) of the beam, as well as for the divergence. The corresponding etendue will be conserved in a CPC. In this case it will be beneficial to use a CPC with rectangular light input and exit facets having the desired height/width ratio of the display panel used. For a spot light application, the requirements are less severe. The light exit facet of the CPC may be circular, but may also have another shape (e.g. rectangular) to illuminate a particularly shaped area or a desired pattern to project such pattern on screens, walls, buildings, infrastructures etc. . . . Although CPCs offer a lot of flexibility in design, their length can be rather large. In general, it is possible to design shorter optical elements with the same performance. To this end, the surface shape and/or the exit surface may be adapted, e.g. to have a more curved exit surface such as to concentrate the light. One additional advantage is that the CPC can be used to overcome possible aspect ratio mismatches when the size of the light guide is restrained by the dimensions of the LED and the size of the light exit facet is determined by the subsequent optical components. Furthermore, it is possible to place a mirror (not shown) partially covering the light exit facet of the CPC, e.g. using a mirror which has a ‘hole’ near or in its center. In this way the exit plane of the CPC is narrowed down, part of the light is being reflected back into the CPC and the light guide, and thus the exit etendue of the light would be reduced. This would, naturally, decrease the amount of light that is extracted from the CPC and light guide. However, if this mirror has a high reflectivity, like e.g. Alanod 4200AG, the light can be effectively injected back into the CPC and light guide, where it may be recycled by TIR. This will not change the angular distribution of the light, but it will alter the position at which the light will hit the CPC exit plane after recycling thus increasing the luminous flux. In this way, part of the light, that normally would be sacrificed in order to reduce the system etendue, can be re-gained and used to increase for example the homogeneity. This is of major importance if the system is used in a digital projection application. By choosing the mirror in the different ways, the same set of CPC and light guide can be used to address systems using different panel sizes and aspect ratio's, without having to sacrifice a large amount of light. In this way, one single system can be used for various digital projection applications.

By using any one of the above structures described with reference to FIG. 2, problems in connection with extracting light from the high-index substrate, or light guide, material to a low-index material like air, particularly related to the efficiency of the extraction, are solved.

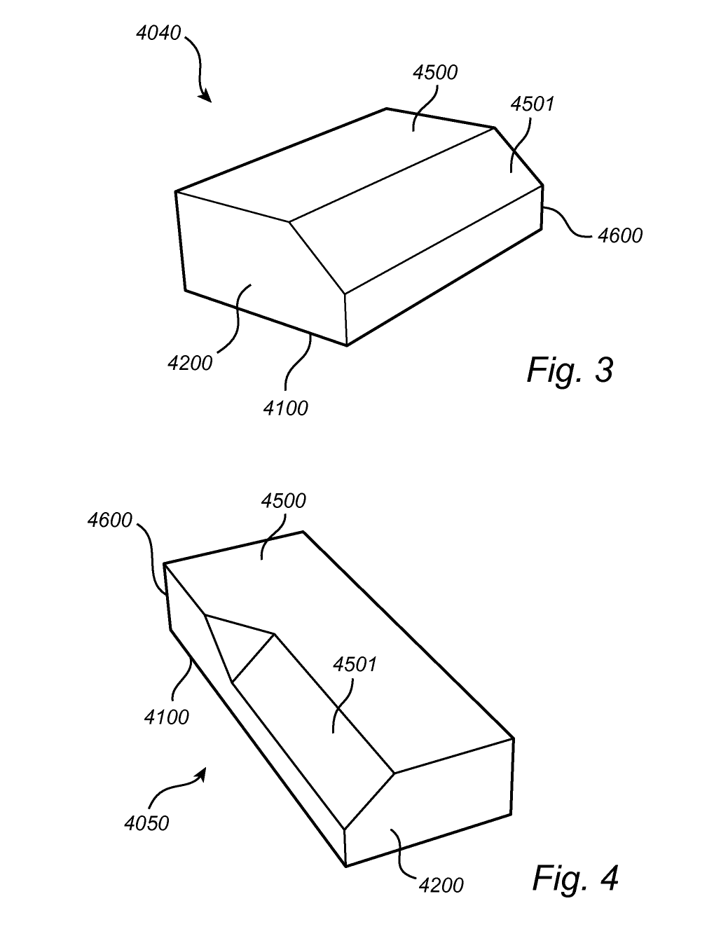

With reference to FIGS. 3 and 4 different possibilities for providing a light distribution having a particular shape will be described. FIG. 3 shows a perspective view of a transparent substrate or light guide 4040 which is shaped throughout its length in order to provide a shaped light exit surface 4200. The light guide 4040 may be a transparent light guide or a light guide adapted for converting light with a first spectral distribution to light with a second spectral distribution. A part 4501 of the light guide 4040 extending throughout the length of the light guide 4040, particularly adjacent to the surface 4500 and opposite to the light input surface 4100, has been removed such as to provide the light guide 4040 with a shape corresponding to the desired shape of the light distribution at the light exit surface 4200, the shape extending throughout the entire length of the light guide 4040 from the light exit surface 4200 to the opposite surface 4600.

FIG. 4 shows a side view of a transparent substrate or light guide 4050 which is shaped over a part of its length such as to provide a shaped light exit surface 4200. The light guide 4050 may be a transparent light guide or a light guide adapted for converting light with a first spectral distribution to light with a second spectral distribution. A part 4501 of the light guide 4050 extending over a part of the length of the light guide 4050 has been removed, particularly adjacent to the surface 4500 and opposite to the light input surface 4100, such as to provide the light guide 4050 with a shape corresponding to the desired shape of the light distribution at the light exit surface 4200, the shape extending over a part of the length of the light guide 4050 adjacent the light exit surface 4200.

Another part or more than one part of the light guide may be removed such as to provide for other shapes of the light exit surface. Any feasible shape of the light exit surface may be obtained in this way. Also, the light guide may be divided partly or fully into several parts having different shapes, such that more complex shapes may be obtained. The part or parts removed from the light guide may be removed by means of e.g. sawing, cutting or the like followed by polishing of the surface that is exposed after the removal of the part or parts. In another alternative a central part of the light guide may be removed, e.g. by drilling, such as to provide a hole in the light exit surface.

In an alternative embodiment, a light distribution having a particular shape may also be obtained by surface treating, e.g. roughening, a part of the light exit surface of the transparent substrate or light guide, whilst leaving the remaining part of the light exit surface smooth. In this embodiment no parts of the light guide need to be removed. Likewise any combination of the above possibilities for obtaining a light distribution having a particular shape is feasible.

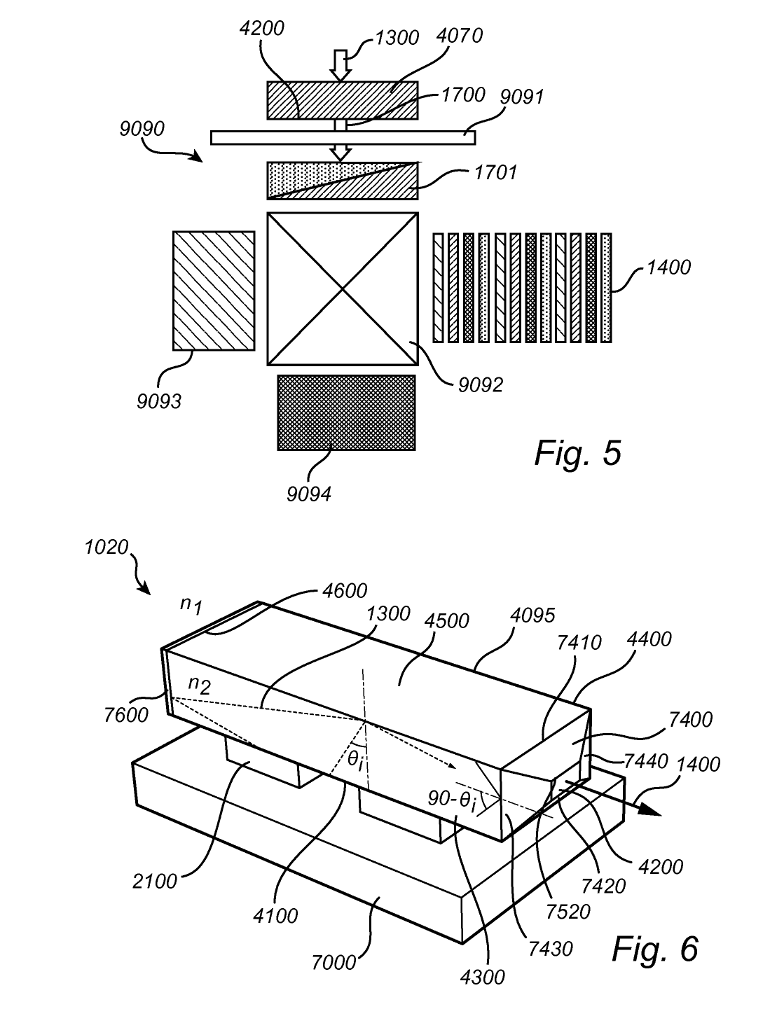

FIG. 5 shows a side view of a lighting system, e.g. a digital projector, with a light guide 4070 which is adapted for converting incident light 1300 in such a way that the emitted light 1700 is in the yellow and/or orange wavelength range, i.e. roughly in the wavelength range of 560 nm to 600 nm. The light guide 4070 may e.g. be provided as a transparent garnet made of ceramic materials such as Ce-doped (Lu,Gd)₃Al₅O₁₂, (Y,Gd)₃Al₅O₁₂ or (Y,Tb)₃Al₅O₁₂. With higher Ce-content and/or higher substitution levels of e.g. Gd and/or Tb in favor of Ce, the spectral distribution of the light emitted by the light guide can be shifted to higher wavelengths. In an embodiment, the light guide 4070 is fully transparent.

At the light exit surface 4200 an optical element 9090 is provided. The optical element 9090 comprises a filter 9091 for filtering the light 1700 emitted from the light guide 4070 such as to provide filtered light 1701, at least one further light source 9093, 9094 and an optical component 9092 adapted for combining the filtered light 1701 and the light from the at least one further light source 9093, 9094 such as to provide a common light output 1400.

The filter 9091 may be an absorption filter or a reflective filter, which may be fixed or switchable. A switchable filter may e.g. be obtained by providing a reflective dichroic mirror, which may be low-pass, band-pass or high-pass according to the desired light output, and a switchable mirror and placing the switchable mirror upstream of the dichroic mirror seen in the light propagation direction. Furthermore, it is also feasible to combine two or more filters and/or mirrors to select a desired light output. The filter 9091 shown in FIG. 5 is a switchable filter enabling the transmission of unfiltered yellow and/or orange light or filtered light, particularly and in the embodiment shown filtered red light, according to the switching state of the filter 9091. The spectral distribution of the filtered light depends on the characteristics of the filter 9091 employed. The optical component 9092 as shown may be a cross dichroic prism also known as an X-cube or it may in an alternative be a suitable set of individual dichroic filters.

In the embodiment shown two further light sources 9093 and 9094 are provided, the further light source 9093 being a blue light source and the further light source 9094 being a green light source. Other colors and/or a higher number of further light sources may be feasible too. One or more of the further light sources may also be light guides according to embodiments of the invention as set forth below. A further option is to use the light filtered out by the filter 9091 as a further light source. The common light output 1400 is thus a combination of light 1701 emitted by the light guide 4070 and filtered by the filter 9091 and light emitted by the respective two further light sources 9093 and 9094. The common light output 1400 may advantageously be white light.

The solution shown in FIG. 5 is advantageous in that it is scalable, cost effective and easily adaptable according to the requirements for a given application of a light emitting device according to embodiments of the invention.

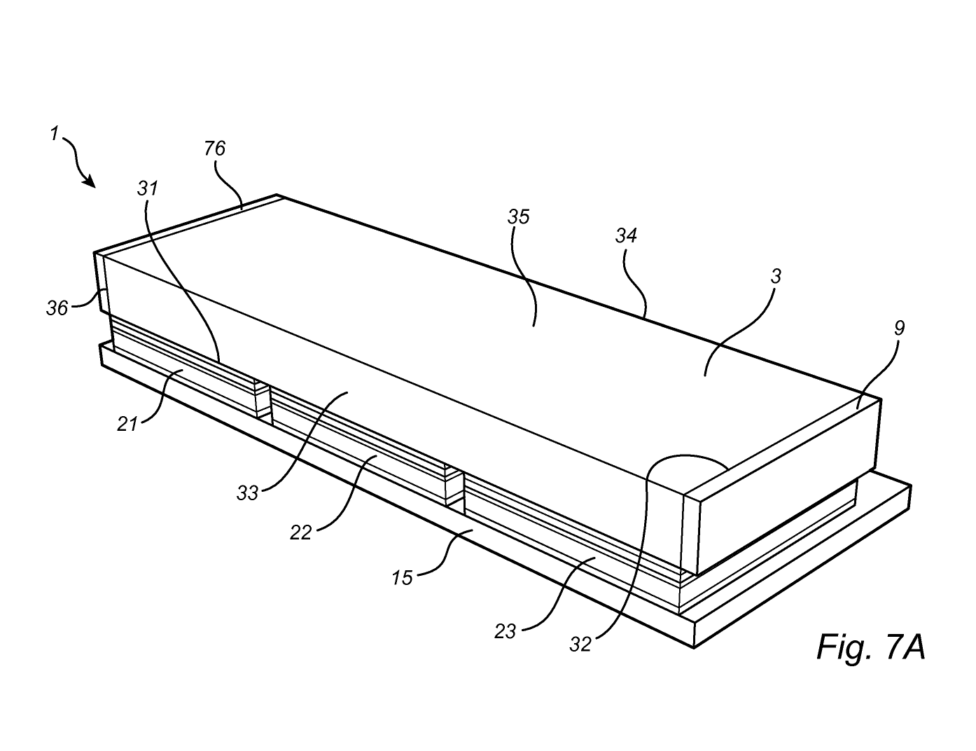

FIG. 6 shows a light emitting device 1020 comprising a plurality of light sources 2100 on a transparent substrate or light guide 4095. The plurality of light sources 2100 is in this example arranged on a base or substrate in the form of a heat sink 7000, in embodiments made of a metal such as copper, iron or aluminum. It is noted that in other embodiments the base or substrate need not be a heat sink. The light guide 4095 is shown shaped generally as a bar or rod having a light input surface 4100 and a light exit surface 4200 extending in an angle different from zero, in this particular case perpendicular, with respect to one another such that the light exit surface 4200 is an end surface of the light guide 4095. The light input surface 4100 and the light exit surface 4200 may have different sizes, in embodiments such that the light input surface 4100 is larger than the light exit surface 4200.

The light guide 4095 further comprises a further surface 4600 extending parallel to and opposite the light exit surface 4200, the further surface 4600 thus likewise being an end surface of the light guide 4095. The light guide 4095 further comprises side surfaces 4300, 4400, 4500. The light guide 4095 may also be plate shaped, e.g. as a square or rectangular plate.

The light emitting device 1020 further comprises a first mirror element 7600 arranged at the further surface 4600 of the light guide 4095 as well as a second mirror element 7400 arranged at the light exit surface 4200 of the light guide 4095. As shown the first mirror element 7600 is arranged in optical contact with the light exit surface 4200 and the second mirror element 7600 is arranged in optical contact with the further surface 4600.

Alternatively, a gap may be provided between one or both of the first and the second mirror element 7600 and 7400 and the further surface 4600 and the light exit surface 4200, respectively. Such a gap may be filled with e.g. air or an optical adhesive.

The light exit surface 4200 of the light guide 4095 is further provided with four inwardly tapered walls and a central flat part extending parallel with the further surface 4600. By “tapered wall” as used herein is meant a wall segment of the light exit surface 4200 which is arranged in an angle different from zero degrees to both the remaining part(s) of the light exit surface and to the surfaces of the light guide extending adjacent to the light exit surface. The walls are tapered inwardly, meaning that the cross-section of the light guide is gradually decreasing towards the exit surface. In this embodiment a second mirror element 7400 is arranged at, and is in optical contact with, the tapered walls of the light exit surface 4200. Hence, the second mirror element is provided with four segments 7410, 7420, 7430 and 7410 corresponding to and covering each of the tapered walls of the light exit surface 4200. A through opening 7520 corresponding to the central flat part of the light exit surface 4200 defines a transparent part of the light exit surface 4200 through which light may exit to be emitted from the light emitting device 1020.

In this way a light emitting device is provided in which the light rays that hit the second mirror element change angular direction such that more light rays are directed towards the light exit surface 4200 and light rays that previously would remain within the light guide 4095 due to TIR due to the change in angular directions now hit the light exit surface 4200 with angles smaller than the critical angle of reflection and consequently may leave the light guide through the through opening 7520 of the light exit surface 4200. Thereby the intensity of the light emitted by the light emitting device through the light exit surface 4200 of the light guide 4095 is increased further. Particularly, when the light guide is a rectangular bar, there will be light rays that hit the second mirror element at the exit surface perpendicularly, and as such cannot leave the bar since they remain bouncing between the two mirror elements. When one mirror element is tilted inwards, the light rays change direction after being reflected at that mirror element and may leave the light guide via the transparent part of the second mirror element. Thus, this configuration provides for improved guidance of light towards the central flat part of the light exit surface 4200 and thus the through hole 7520 in the second mirror element 7400 by means of reflection off of the tapered walls.

In alternative embodiments other numbers of tapered walls, such as less or more than four, e.g. one, two, three, five or six tapered walls, may be provided, and similarly not all tapered walls need be provided with a second mirror element or segments thereof. In other alternatives, one or more of the tapered walls may be uncovered by the second mirror element 7400, and/or the central flat part may be covered partly or fully by the second mirror element 7400.

FIG. 7A shows a perspective view of a light emitting device 1 according to a first and general embodiment of the invention, and FIG. 7B shows the light emitting device 1 according to FIG. 7A in a cross sectional view. The light emitting device 1 generally comprises plurality of solid state light sources 21, and a transparent substrate 3. Suitable types of solid state light sources are described above. In the following all solid state light sources are for the sake of simplicity shown and described as light emitting diodes (LEDs).

In the embodiment shown in FIGS. 7A and 7B three LEDs 21, 22 and 23 are provided. However, any feasible number of LEDs may in principle be provided. For example ten LEDs or twenty LEDs may be used.

The transparent substrate 3 is shown shaped generally as a bar or rod having a first light input surface 31 and a first light exit surface 32 extending perpendicular to one another such that the first light exit surface 32 is an end surface of the transparent substrate 3. The transparent substrate 3 further comprises a further surface 36 extending parallel to and opposite the first light exit surface 32, the further surface 36 thus likewise being an end surface of the transparent substrate 3. The transparent substrate 3 further comprises side surfaces 33, 34, 35. The transparent substrate 3 may also be plate shaped, e.g. as a square or rectangular plate. In that case the plurality of light sources may be arranged as a square or two-dimensional array.

The first light input surface 31 and the first light exit surface 32 generally extend in an angle different from zero with respect to each other. In the embodiments shown herein the first light input surface 31 and the first light exit surface 32 extend perpendicular to each other. Also, the first light input surface 31 and the first light exit surface 32 may have different sizes, such that the first light input surface 31 is larger than the first light exit surface 32.

Alternative configurations of the light emitting device according to the invention in which the first light exit surface 32 and the further surface 36 are mutually opposite side surfaces and the first light input surface 31 is an end surface are also feasible.

The transparent substrate 3 shown in FIGS. 7A and 7B is made of a transparent material, suitable transparent materials being described above. A particularly advantageous material for the substrate 3 is, however, doped or undoped sapphire. The transparent substrate 3 may alternatively be made of a doped or undoped garnet, suitable garnets being described above. Furthermore, the transparent substrate 3 may be luminescent, light concentrating or a combination thereof, suitable materials being described above. Thereby a light emitting device having a transparent substrate with particularly good light guiding properties and particularly good wavelength conversion properties is provided.

The transparent substrate has a thickness or height H defined as the distance between and perpendicular to both the first light input surface 31 and the surface 35. The width W of the transparent substrate is defined as the distance between and perpendicular to both the surface 33 and the surface 34. The length L of the transparent substrate is defined as the distance between and perpendicular to both the first light exit surface 32 and the further surface 36.

The height H is in embodiments <10 mm, in other embodiments <5, and in yet other embodiments <2 mm. The width W is in embodiments <10 mm, in other embodiments <5, in yet other embodiments <2 mm. The length L is in embodiments larger than the width W and the height H, in other embodiments at least 2 times the width W or 2 times the height H, in yet other embodiments at least 3 times the width W or 3 times the height H. The aspect ratio of the Height H:Width W is typically 1:1 (for e.g. general light source applications) or 1:2, 1:3 or 1:4 (for e.g. special light source applications such as headlamps) or 4:3, 16:10, 16:9 or 256:135 (for e.g. display applications). For example, the light guide comprises a height H of 2 mm, a width W of 4 mm, and a length L of 20 mm. In another example, the light guide comprises a height H of 1.5 mm, a width W of 2.4 mm, and a length L of 30 mm.

Generally transparent substrates and light guides as used in the invention comprise a light input surface and a light exit surface. The light exit surface can have any shape, but is in embodiments shaped as a square, rectangle, round, oval, triangle, pentagon, or hexagon. Other embodiments of the light exit surface are described above.

The generally rod shaped or bar shaped transparent substrate or light guide can have any cross sectional shape, but in embodiments has a cross section the shape of a square, rectangle, triangle, pentagon, or hexagon, other suitable embodiments being described above.

Generally, transparent substrates or light guides as used in the invention are cuboid, but may be provided with a different shape than a cuboid, with the light input surface having somewhat the shape of a trapezoid. By doing so, the light flux may be even enhanced, which may be advantageous for some applications.

The LEDs 21, 22, 23 are arranged at the first light input surface 31 of the transparent substrate 3 such as to emit light into the transparent substrate 3.

The LEDs 21, 22, 23 may be any feasible type of LED, such as a traditional semiconductor Light Emitting Diode (LED) or a Laser Diode or Organic Light Emitting Diode (OLED) or an array of a traditional semiconductor LEDs or Laser Diodes or OLEDs. in embodiments, the at least one LED emits light in the infrared, the visible or the ultraviolet wavelength range. The LEDs 21, 22, 23 may be manufactured in any feasible manner known in the art, such as by a chemical or physical deposition method or by Liquid Phase Epitaxy (LPE), the manufacture or growing of the LEDs 21, 22, 23 being carried out directly onto the transparent substrate 3.

The LEDs 21, 22, 23 are arranged in a row and in direct physical and optical contact with the transparent substrate 3, by being provided, e.g. the active layers of the LEDs are grown, directly onto the transparent substrate 3 and are processed, e.g. etched, directly on the transparent substrate 3. In other words, the transparent substrate 3 is the substrate on which the LEDs, i.e. the active layers of the LEDs, are manufactured. Suitable manufacturing techniques are applied to provide a separation, or gap, between neighboring or adjacent LEDs. The direct physical contact between the active layers of the plurality of LEDs 21, 22, 23 and the transparent substrate 3 results in a matching lattice structure at the first light input surface 31 of the active layers of the plurality of LEDs 21, 22, 23 and the transparent substrate 3. In other words, the crystal structure of the active layers of the plurality of LEDs matches, or is substantially similar to, the crystal structure of the transparent substrate 3 at the first light input surface 31, meaning that there is a smooth transition of the crystal structure from the transparent substrate 3 to the active layers of the plurality of LEDs 21, 22, 23 thereby reducing, for example, scattering losses at the first light input surface 31. As already mentioned, this may be the result of growing, for example using epitaxial growth, the active layers of the plurality of LEDs 21, 22, 23 directly on the first light input surface 31 of the transparent substrate 3, resulting in the matching lattice structure. The transparent substrate 3 is for example a growth substrate and/or a single crystal substrate. These substrates provide for improved coupling of light into the transparent substrate 3 emitted by the plurality of LEDs, because of the smooth transition between the active layers of the plurality of LEDs and the transparent substrate 3 at the first light input surface 31.

In an embodiment the LEDs 21, 22, 23 emit light 13 having the same spectral distribution, namely a first spectral distribution. Alternatively, two or more of the LEDs 21, 22, 23 may be emitting light having different spectral distributions, such as e.g. red, green and blue. In a further alternative each LED may be provided on its own transparent substrate.

In embodiments the LEDs 21, 22, 23 emit light in the visual part of the spectrum. The LEDs may emit light having a central emission wavelength within a blue color-range. The LEDs may also emit light having a central emission wavelength within a green color-range. The LEDs may also emit light having a central emission wavelength within a red color-range. In this connection, the blue color-range is defined as wavelengths between 380 nanometer and 495 nanometer, the green color-range is defined as wavelengths between 495 nanometer and 590 nanometer, and the red color-range is defined as wavelengths between 590 nanometer and 800 nanometer.

The LEDs 21, 22, 23 are arranged on a common base or substrate 15, such that the LEDs are arranged between the transparent substrate 3 and the base or substrate 15. The base or substrate 15 is in an embodiment a metallic substrate, which may be in the form of a heat sink, in embodiments made of a metal such as copper, iron or aluminum. The heat sink may comprise fins for improved heat dissipation. It is noted that in other embodiments the base or substrate 15 need not be a common base or substrate or a heat sink. By providing a heat sink the heat produced by the light source may in an efficient manner be dissipated away from the light guide. By providing a metallic substrate a considerable improvement in the dissipation of heat away from the LED and thus away from the transparent substrate is obtained, thus raising the maximum obtainable output light intensity of the light emitting device considerably. Furthermore, the adverse effects on the optical performance due to e.g. thermal quenching are lowered significantly or even eliminated, which provides for a considerably more reliable light emitting device with an improved optical performance. This in turn provides for a raise in the maximum obtainable output light intensity of the light emitting device as well as for lowering or even eliminating the adverse effects on the optical performance of the light emitting device caused by excess heat in the light guide. The base or substrate 15 or heat sink is, however, not an essential element, and may thus in yet other embodiments be omitted.

The base or substrate 15 is in an embodiment made of a material having a thermal conductivity being larger than 1 W/(K*m), larger than 10 W/(K*m) or even larger than 20 W/(K*m).

The light emitting device 1 generally works as follows. Light having a first spectral distribution is emitted by the LEDs 21, 22, 23 and transmitted through the transparent substrate 3 entering at the first light input surface 31, being guided by TIR (Total Internal Reflection) through the transparent substrate and exiting at the first light exit surface 32. In principle, however, not all light need be transmitted through the light exit surface 32 as some of the light may be transmitted e.g. through the surface 35.

The transparent substrate 3 shown in FIGS. 7A and 7B further comprises in this example a reflective element 76 arranged at the further surface 36, an element 9 for coupling light out of the transparent substrate arranged at the first light exit surface 32 and a coupling structure 7 for coupling light into the transparent substrate arranged at the first light input surface 31, all being optional elements.

The reflective element 76 may e.g. be any one of a mirror plate, a mirror foil and a mirror coating which reduces the loss of light occurring through the surfaces 33, 34, 35 and 36.

The coupling of light from the LEDs 21, 22, 23 into the transparent substrate 3 may be improved by means of an appropriate coupling structure 7 provided on or in the first light input surface 31 (cf. FIG. 7B). In principle more than one coupling structure 7 may be provided.

Furthermore, an out-coupling structure 9 for coupling light out of the transparent substrate may be provided. The out-coupling structure 9 may e.g. be a grating or a photonic crystal, and is provided for improving the coupling of light out of the transparent substrate 3. The out-coupling structure 9 is in an embodiment arranged on the first light exit surface 32. Alternatively the out-coupling structure 9 may be embedded in the transparent structure adjacent to the first light exit surface 32.

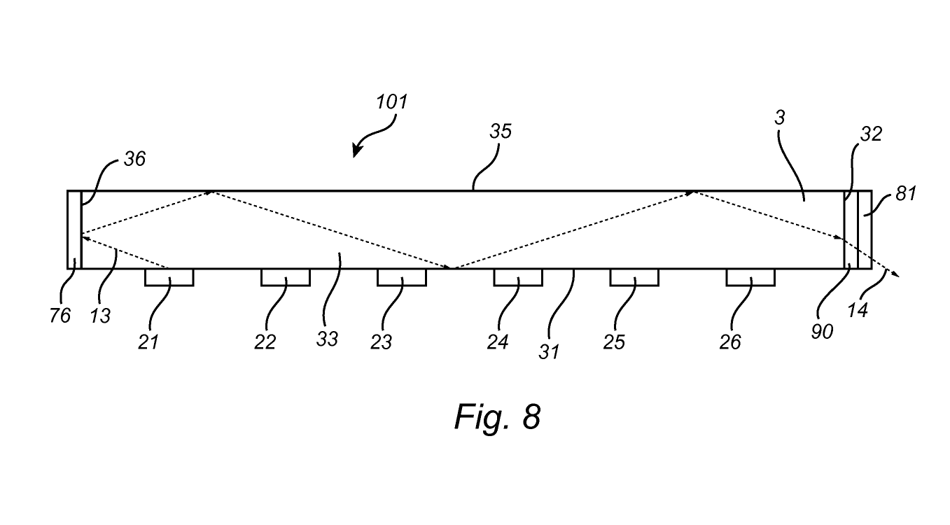

Turning now to FIG. 8, a second embodiment of a light emitting device 101 according to the invention is shown in a side view. In this embodiment, the light emitting device 101 comprises a total of six LEDs 21, 22, 23, 24, 25, 26 arranged in a row.

In this embodiment the transparent substrate 3 of the light emitting device 101 is adapted for converting light 13 with the first spectral distribution emitted by the LEDs 21, 22, 23, 24, 25, 26 to light 14 with a second spectral distribution. Thus, the transparent substrate 3 of the light emitting device 101 is in this embodiment a luminescent transparent substrate or a transparent substrate comprising a luminescent material or a suitable dopant. Suitable luminescent materials and dopants are described above. In the embodiment shown in FIG. 8, the transparent substrate 3 comprises a luminescent element 90 for converting the light 13 with the first spectral distribution to light 14 with a second spectral distribution, the luminescent element 90 being arranged at the first light exit surface 32.

In another embodiment the light transparent substrate is adapted for converting light 13 emitted by the LEDs in the form of a UV to blue wavelength converter and a phosphor is provided at the first light exit surface 32 adapted to emit white light based on the blue light input from the transparent substrate. Hence, the plurality of LEDs 21, 22, 23, 24, 25, 26 emit light in the UV to blue wavelength range. The transparent substrate comprises for example a polycrystalline cubic Yttrium Aluminum Garnet (YAG), doped with rare earth ions, for example Europium and/or Terbium, while the phosphor at the first light exit surface 32 is a yellow phosphor. This embodiment is advantageous in that the surface area of the light exit surface is smaller than the surface area required to build a light source consisting of direct light emitting LEDs. Thereby, a gain in etendue can be realized. Alternatives for generating white light with a blue or UV light source include but are not limited to LEDs emitting blue light, which light is converted to green/blue light in the transparent substrate, which in turn is converted to white light by a red phosphor at the first light exit surface, and LEDs emitting blue light, which light is converted to green light in the transparent substrate, which in turn is mixed with red and blue light to generate a white LED source, wherein the mixing is achieved by means of a red phosphor in front of which a diffusor is arranged. Furthermore, in this embodiment an optical element 81 is arranged at the first light exit surface 32 of the transparent substrate 3. Suitable optical elements include, but are not limited to, refractive or diffractive elements, e.g. lenses, color filters, reflective elements, polarizers and pinholes as well as combinations of such elements. In alternative embodiments, more than one optical element may be provided. The provision of an optical element 81 may contribute to one or more of shaping, filtering and focusing the emitted light beam.

Furthermore, in this embodiment a reflective element 76 is arranged at the surface 36 extending opposite and parallel to the first light exit surface 32 of the transparent substrate 3. Providing the transparent substrate 3 of the light emitting device 101 with such a reflective element 76, which may e.g. be a mirror element, positioned at a surface extending parallel to and opposite the desired light exit surface results in that the light rays incident on this reflective element will be reflected back through the transparent substrate to the desired light exit surface of the transparent substrate, where the light rays may leave the transparent substrate. Thereby the light intensity of the light leaving through the desired light exit surface is increased. Also, the amount of light lost through transparent substrate surfaces other than the light exit surface is lowered considerably.

In other embodiments (not shown) a light emitting device is provided comprising two or more transparent substrates each with a plurality of solid state light sources.

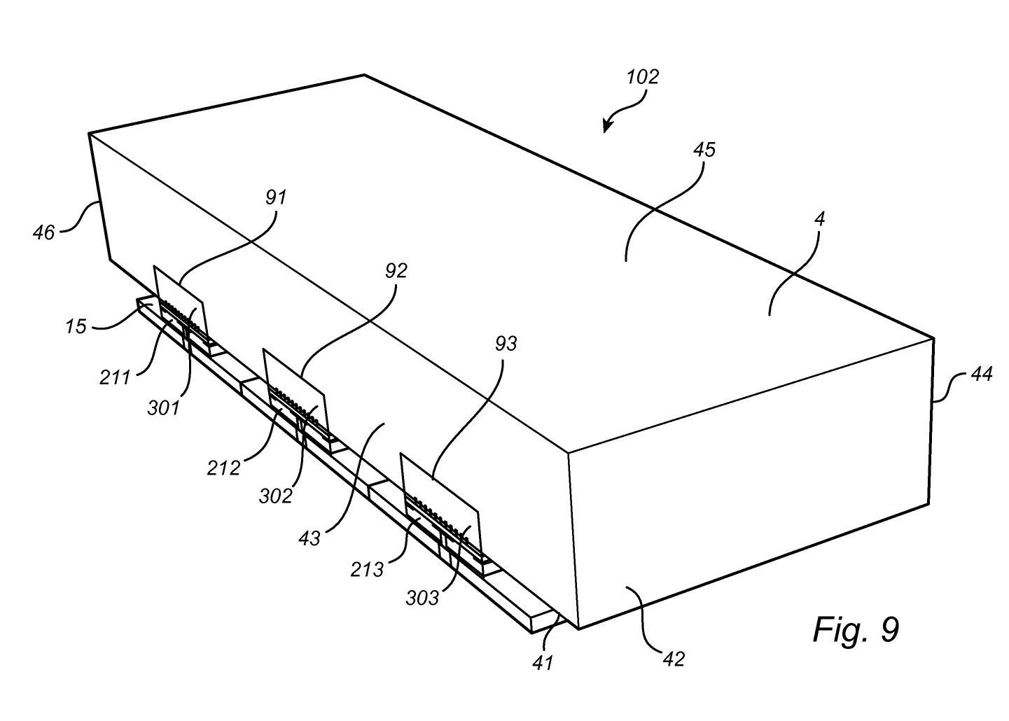

Turning now to FIG. 9, a third embodiment of a light emitting device 102 according to the invention is shown in a perspective view.

The light emitting device 102 comprises a light guide 4 and three LEDs 211, 212, 213, the three LEDs being provided on a respective transparent substrate 301, 302 and 303.

The light guide 4 is arranged such as to surround the transparent substrates 301, 302 and 303 on three sides, namely the light exit surface and the surfaces extending parallel and opposite to the light input surface and the light exit surface, respectively. In the embodiment shown this is obtained by arranging the transparent substrates 301, 302, 303 in respective corresponding cut-outs or recesses 91, 92, 93 in the light guide 4. In an alternative the transparent substrates 301, 302 and 303 may be arranged embedded in the light guide 4.

In alternative embodiments the light guide may be arranged such as to surround the transparent substrate on more than three sides, possibly on all sides 32, 33, 34, 35, 36 apart from the light input side 31. The light guide 4 may only extend onto parts of the first light input surface 31 of the transparent substrate 3 not being covered by the at least one LED.

The light guide 4 is shown shaped generally as a bar or rod having a second light input surface 41 and a second light exit surface 42 extending perpendicular to one another such that the second light exit surface 42 is an end surface of the light guide 4. The light guide 4 further comprises a further surface 46 extending parallel to and opposite the second light exit surface 42, the further surface 46 thus likewise being an end surface of the light guide 4. The light guide 4 further comprises side surfaces 43, 44, 45. The light guide 4 may also be plate shaped, e.g. as a square or rectangular plate.

The second light input surface 41 and the second light exit surface 42 generally extend in an angle different from zero with respect to each other. In the embodiments shown herein the second light input surface 41 and the second light exit surface 42 extend perpendicular to each other. Also, the second light input surface 41 and the second light exit surface 42 may have different sizes, in embodiments such that the second light input surface 41 is larger than the second light exit surface 42.

Alternative configurations of the light emitting device according to the invention in which the second light exit surface 42 and the further surface 46 are mutually opposite side surfaces and the second light input surface 41 is an end surface are also feasible.

The light guide 4 shown in FIG. 9 is a transparent light guide. Suitable transparent materials are described above. The light guide 4 may alternatively be made of a garnet, suitable garnets being described above. Furthermore, the light guide 4 may be luminescent, light concentrating or a combination thereof, suitable materials being described above.

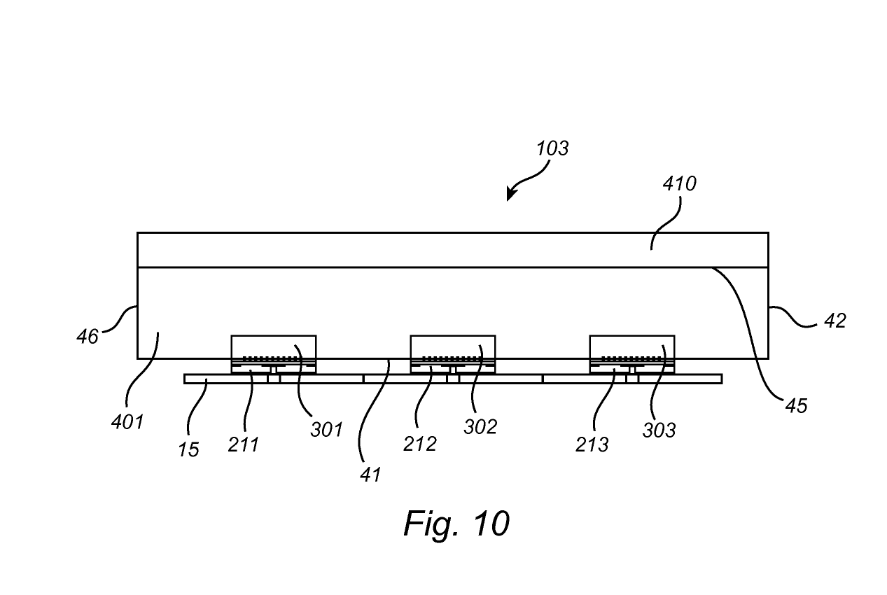

Turning now to FIG. 10, a fourth embodiment of a light emitting device 103 according to the invention and being very similar to the light emitting device 102 shown in FIG. 9 is shown in a side view.

The light emitting device 103 shown in FIG. 10 differs from that of FIG. 9 in that it comprises a luminescent element, layer or material 410 arranged at the surface 45 opposite and parallel to the second light input surface 41. Thus, the light guide 4 is here adapted for converting at least a part of the light received from the transparent substrates 301, 302, 303 to light with a different spectral distribution, which is then emitted through the second light exit surface 42. Suitable luminescent materials are described above.

In an alternative, the light guide 4 may be provided with two or more luminescent elements or layers of different luminescent materials such as to converting at least a part of the light received from the transparent substrates 301, 302, 303 to light with two or more different spectral distributions, or in other words to produce two or more different colors.

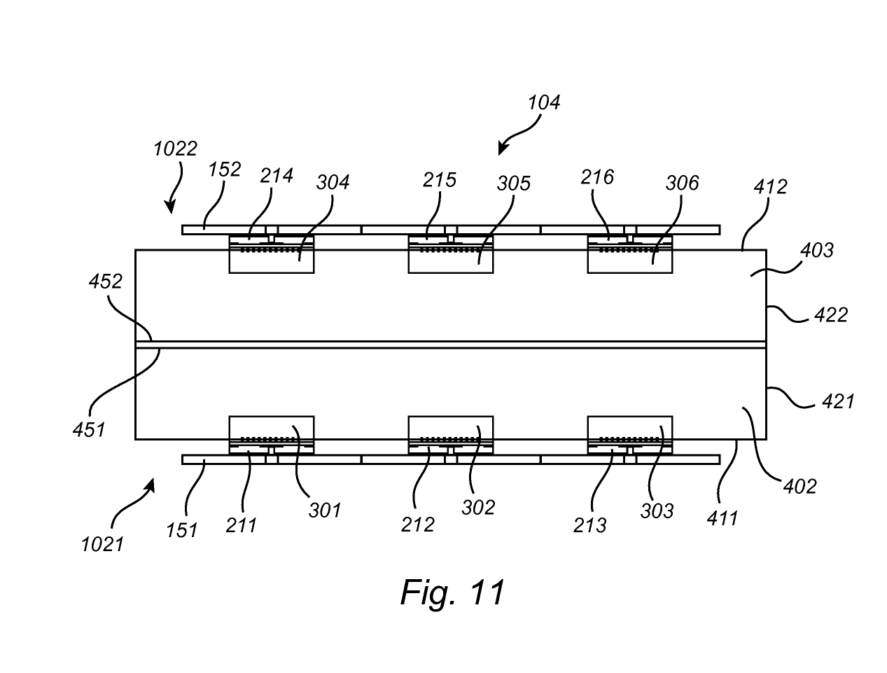

Turning now to FIG. 11, a fifth embodiment of a light emitting device 104 according to the invention is shown in a side view.

The light emitting device 104 differs from the remaining embodiments described herein in that it comprises two light emitting devices 1021 and 1022 of the type shown in FIGS. 7A, 7B, 8 (not shown in FIG. 11) or FIG. 9 and that are described above.

The light emitting devices 1021 and 1022 are arranged such that their respective light exit surfaces 421 and 422 are facing in the same direction and such that their respective surface 451 and 452 extending opposite and parallel to their respective light input surfaces 411 and 412 are arranged adjacent to each other, possibly but not necessarily in contact with each other. Thus the light emitting devices 1021 and 1022 are arranged such that their respective light input surfaces 411 and 412 are facing away from each other.

The light emitting device 1021 comprises a light guide 402 and three LEDs 211, 212, 213, the three LEDs being provided on their respective transparent substrate 301, 302 and 303. Likewise, the light emitting device 1022 comprises a light guide 403 and three LEDs 214, 215, 216, the three LEDs being provided on their respective transparent substrate 304, 305 and 306.

In an embodiment the LEDs 211, 212, 213 emit light in the blue color range defined above, while the LEDs 214, 215, 216 emit light in the red color range defined above. The light emitting device 104 thus enables combining LEDs emitting light of different colors in one light emitting device in a simple and convenient manner.

However, the LEDs 211, 212, 213, 214, 215, 216 may also emit light having one and the same spectral distribution, or light having more than two mutually different spectral distributions.

In a further exemplary embodiment a light emitting device comprising more than two light emitting devices 1021, 1022 of the type shown in FIG. 7A, 7B, 8 or 9 and described above is also feasible.

Also, in alternative embodiments, the light guides 4, 401, 402 described in connection with FIGS. 9-11 may also comprise any one or more of a reflective element, a coupling structure for coupling light into or out of the light guide and an optical element as those described for the transparent substrate 3 in connection with FIGS. 7A-8 above. The light emitting devices according to the embodiments of the invention as described above may controlled by a control device connected to the light sources by means of suitable electrical connections. The control device is capable of controlling the current supplied to the light sources and thereby the intensity with which the light sources emit light individually. In general the control device may be adapted for controlling the current, voltage and/or even the frequency of the power applied to the light source(s). The electrical connections may be wired connections or a wireless connections. When the light emitting device operates in a full power mode, all light sources emit light at maximum intensity. In an embodiment, a power saving mode is enabled by dimming one of the light sources, or LEDs, and wherein the other light source or light sources that is/are arranged at the largest distance, i.e. the farthest away, from the first light exit surface are switched off. In this way improved energy saving is achieved by starting dimming the light source, or LED, that is arranged furthest away from the light exit surface, because the light originating from this light source (and which will at least partly be converted in the light guide) travels the largest distance through the light guide to the first light exit surface and thus will experience the most losses through, for example, absorption. In other words, the most efficient light source will be dimmed the latest and is the light source that is arranged at the closest distance to the first light exit surface, because the light originating from this light source (and which will in embodiments at least partly be converted in the light guide) has to travel the shortest distance through the light guide to the first light exit surface and thus will experience less absorption losses. In an embodiment the control device is adapted for dimming the light sources one by one, thereby providing for further degrees of freedom in dimming.

In another embodiment a control device is provided adapted for controlling a first power supply to a first light emitting device, or light guide, according to the invention, and for controlling a second power supply to a second light emitting device, or light guide, according to the invention separately such as to provide the light emitted in combination by the light emitting devices with a desired beam pattern or shape. The term “beam pattern” as used herein is intended to refer to the appearance of the light emitted by all light guides of a light emitting apparatus seen as a whole, as expressed in terms of one or more of at least the size and shape of the light as seen when projected onto a surface and the intensity and color of the light. Particularly the control device is adapted for controlling the current, voltage and/or even the frequency of the power applied to the first light source and the second light source, respectively, separately from one another.

By providing at least two light emitting devices according to the invention, or also named light guides, each having separate light sources, and by providing a control device for controlling the power supply to the light sources of each light guide separately, a light emitting apparatus is provided with which it becomes possible to change the intensity of the light emitted from each of the light guides separately, and with which these changes may be performed with a very large degree of precision in terms of providing an exact intensity level, especially an exact high intensity level, desired in a specific application. This in turn provides for that the overall intensity of the light emitted by the light emitting apparatus may be changed in a simple manner with a large degree of freedom and a high degree of precision. Also, a light emitting apparatus which is efficient and energy saving is provided. This makes such a light emitting apparatus especially suitable for use in applications including but not limited to automotive lighting and projection devices. Furthermore, by providing a control device for controlling the power supply to the light sources of each light guide separately, a light emitting apparatus is provided with which it becomes possible to control the beam pattern of the light emitted from each of the light guides separately and thus to obtain at least a first beam of light and a second beam of light which is different from the first beam of light. In an embodiment each of the light guides comprises an optical element provided at the light exit surfaces. In this way high intensity image patterns and shapes, which may be obtained by means of the light emitting apparatus, may be adjusted to a specific application or situation. For instance the image pattern obtained may be filtered, such as filtered by color or polarization, focused, shaped or projected onto a surface. Suitable optical elements include, but are not limited to, refractive or diffractive elements, e.g. lenses, color filters, reflective elements, polarizers and pinholes as well as combinations of such elements.

In other embodiments one or more sensors may be provided adapted for providing an input signal to the control device, wherein the control device is adapted for controlling the first power supply of the first light source and the second power supply of the second light source separately in response to the input signal. Thereby the intensity and/or the pattern of the light emitted from each of the light guides may be controlled in response to parameters indicating specific conditions and/or requirements in the surroundings and/or changes of conditions and/or requirements to be fulfilled by the light emitting apparatus in order to achieve optimal lighting, such as for example wet roads in case of automotive head lights. The sensors may for example be selected from a group comprising a steering wheel angle sensor, a speed or velocity sensor, a road bend sensor, a radial force sensor, an inclination sensor, a GPS-sensor, a light sensor, a weather sensor, a presence detection sensor, a distance measurement sensor, a temperature sensor, a humidity sensor and a camera. In principle, however, the sensors may be any type of sensor feasible. Also, any number of sensors other than one, e.g. two or more, may be provided.

In one example such a light emitting apparatus equipped with one or more sensors is used in an adaptive front lighting system for a vehicle. In such an application, the sensors may be sensors for providing a signal indicating a state of the vehicle, such as its speed, and/or of the surroundings, such as the weather conditions, the road conditions or the natural lighting conditions, and the control device may be adapted to receive the signal indicating a state of the vehicle and/or the surroundings and to control the light sources in dependence of the received signal, and thus in dependence of the state of the vehicle and/or of the surroundings.

In another example, such a light emitting apparatus equipped with one or more sensors is used in a projector. In such an application, in some situations the aspect ratio of the image needs to be adapted and thus some pixel area of the LCD or DLP panel is not used. In this application, the lighting apparatus may provide a beam shape according to the aspect ratio used at a given point of time such that the beam shape may be changed when switching aspect ratio, e.g. from an aspect ratio of 16:9 to an aspect ratio of 4:3.

Although two light guides are mentioned in embodiments of a lighting apparatus with a control device as described above, it is also feasible that the lighting apparatus comprises more than two light guides.

The person skilled in the art realizes that the present invention by no means is limited to the embodiments described above. On the contrary, many modifications and variations are possible within the scope of the appended claims.

Particularly, the various elements and features of the various embodiments described herein may be combined freely.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. A light emitting device comprising:
a plurality of solid state light sources, and
a transparent substrate comprising a first light input surface and a first light exit surface extending in an angle different from zero to one another, the transparent substrate being adapted for receiving light emitted by the plurality of solid state light sources at the first light input surface, guiding the light to the first light exit surface and coupling the light out of the first light exit surface,
wherein active layers of the plurality of solid state light sources are provided in direct physical contact with the first light input surface of the transparent substrate, and wherein the first light input surface has a larger surface area than the first light exit surface.

2. A light emitting device according to claim 1, wherein the area of the first light input surface is four times larger, ten times larger or thirty times larger than the surface area of the first light exit surface.

3. A light emitting device according to claim 1, wherein the transparent substrate is a transparent growth substrate.

4. A light emitting device according to claim 1, wherein the transparent substrate is a single crystal substrate.

5. A light emitting device according to claim 1, wherein a crystal structure of the transparent substrate matches a crystal structure of the active layers of the plurality of light sources at the first light input surface.

6. A light emitting device according to claim 1, wherein the transparent substrate comprises a coupling element arranged at the first light exit surface for coupling light out of the first light exit surface.

7. A light emitting device according to claim 1, wherein the plurality of light sources comprise at least one first solid state light source emitting light of a first spectral distribution and at least one second solid state light source emitting light of a second spectral distribution, different from the first spectral distribution.

8. A light emitting device according to claim 1, wherein the transparent substrate comprises any one or more of a luminescent element and an optical element arranged at the first light exit surface.

9. A light emitting device according to claim 1, wherein the transparent substrate is adapted for converting at least a part of the light emitted by the plurality of solid state light sources to light with a different spectral distribution.

10. A light emitting device according to claim 1, and further comprising a light guide comprising a second light input surface and a second light exit surface,
the light guide being adapted for receiving the light coupled out of the first light exit surface of the transparent substrate at the second light input surface, guiding the received light to the second light exit surface and coupling the received light out of the second light exit surface,
the light guide being arranged such as to surround the transparent substrate at least partially.

11. A light emitting device according to claim 10, wherein the transparent substrate is embedded in the light guide.

12. A light emitting device according to claim 10, wherein the light guide further is adapted for converting at least a part of the light received from the transparent substrate to light with a different spectral distribution.

13. A light emitting device according to claim 10, wherein the light guide comprises any one of a transparent material, a luminescent material, a garnet, a doped garnet and any combination thereof.

14. A lamp, a luminaire, and a lighting system comprising a light emitting device according to any one of the previous claims, the lamp, luminaire and system being used in one or more of the following applications: digital projection, automotive lighting, stage lighting shop lighting, home lighting, accent lighting, spot lighting, theater lighting, fiber optic lighting, display systems, warning lighting systems, medical lighting applications, decorative lighting applications.

15. A method for manufacturing a light emitting device, the method comprising the steps of:
providing a transparent substrate comprising a first light input surface and a first light exit surface extending in an angle different from zero to one another, the transparent substrate being adapted for guiding light, which is received at the first light input surface, to the first light exit surface and coupling the light out of the first light exit surface, wherein the first light input surface has a larger surface area than the first light exit surface, and
growing active layers of a plurality of solid state light sources on the first light input surface of the transparent substrate.
